(19) United States
(12) Patent Application Publication
(10) Pub. No.: US 2026/0029458 A1
(43) Pub. Date: Jan. 29, 2026

(54) SYSTEMS AND METHODS FOR MASSIVELY PARALLEL TRIMMING OF SEMICONDUCTOR DEVICES

(71) Applicant: Anora, LLC, Richardson, TX (US)

(72) Inventors: Sasikumar P. Cherubal, Frisco, TX (US); Pramodchandran N. Variyam, Plano, TX (US); Avinash Virupakshaiah Pura, Allen, TX (US)

(73) Assignee: Anora, LLC, Richardson, TX (US)

(21) Appl. No.: 18/782,444

(22) Filed: Jul. 24, 2024

(51) Int. Cl. G01R 31/26; G06F 30/32

(52) U.S. Cl. CPC G01R 31/2642; G06F 30/32

(57) ABSTRACT

Systems and methods for massively parallel trimming of semiconductor devices include a thermal testing system configured for: receiving a first signal from a device under test, the first signal having an unknown first frequency; receiving a second signal from a local oscillator at a known second frequency; mixing the first signal and the second signal; filtering the mixed signal through a low-pass filter circuit; digitizing the filtered signal into a plurality of digital signal samples; windowing the plurality of digital signal samples within a frequency window; computing a discrete spectrum of the digital signal samples within the frequency window using a Fast Fourier Transform algorithm; fitting a plurality of consecutive frequency bins in the discrete spectrum to an interpolating function; evaluating the unknown first frequency based on the fitting; and electronically trimming the DUT according to the evaluated first frequency.

### BACKGROUND

Semiconductor devices are typically tested to ensure they meet quality standards and performance specifications before they are released for production (i.e., large scale manufacture) or commercial use. Before production, semiconductor devices may be subject to engineering testing, for example, to validate their functionalities, to ensure design standards are met across various temperatures, and to assess their reliability in the field, among other reasons. Such engineering testing may be performed in testing laboratories. Production testing of semiconductor devices, on the other hand, typically takes place in controlled environments such as semiconductor fabrication or assembly facilities. These environments are equipped with specialized testing equipment and tools, such as automated test equipment (ATE), probe stations, test sockets, and test fixtures that enable efficient and accurate testing of semiconductor devices in high-volume production. In some cases, semiconductor devices are tested either in engineering or production under varying temperatures in a thermal chamber.

### BRIEF DESCRIPTION OF DRAWINGS

Embodiments will be readily understood by the following detailed description in conjunction with the accompanying drawings. To facilitate this description, like reference numerals designate like elements. Embodiments are illustrated by way of example, and not by way of limitation, in the figures of the accompanying drawings. For convenience, if a collection of drawings designated with different letters are present (e.g., FIGS. 1A-1D), such a collection may be referred to herein without the letters (e.g., as “FIG. 1”).

FIGS. 1A-1D are simplified diagrams illustrating a system for massively parallel trimming of semiconductor devices, according to an example embodiment.

FIG. 2 is a simplified diagram illustrating example details in the system for massively parallel trimming of semiconductor devices, according to an example embodiment.

FIG. 3 is a simplified diagram showing an example embodiment of the system for massively parallel trimming of semiconductor devices, according to an example embodiment.

FIG. 4 is a simplified block diagram illustrating example details of the system for massively parallel trimming of semiconductor devices, according to an example embodiment.

FIG. 5 is a simplified diagram illustrating example details of the system for massively parallel trimming of semiconductor devices, according to an example embodiment.

FIG. 6 is a simplified block diagram illustrating an example configuration of the system for massively parallel trimming of semiconductor devices, according to an embodiment.

FIGS. 7A-7B are simplified diagrams showing temperature effects in the system for massively parallel trimming of semiconductor devices, according to certain embodiments.

FIG. 8 is a simplified block diagram illustrating an example configuration in the system for massively parallel trimming of semiconductor devices, according to an example embodiment.

FIG. 9 is a simplified flow diagram of an example method for massively parallel trimming of semiconductor devices, according to some embodiments disclosed herein.

### DETAILED DESCRIPTION

### Overview

For purposes of illustrating the embodiments described herein, it is important to understand certain terminology and operations of technology networks. The following foundational information may be viewed as a basis from which the present disclosure may be properly explained. Such information is offered for purposes of explanation only and, accordingly, should not be construed in any way to limit the broad scope of the present disclosure and its potential applications.

In the following detailed description, various aspects of the illustrative implementations may be described using terms commonly employed by those skilled in the art to convey the substance of their work to others skilled in the art.

The term “semiconductor device” means any electronic component that is commonly manufactured using semiconductor materials but can also include components that do not contain any semiconductor materials, for example, integrated circuits (ICs), diodes, transistors, light emitting diodes (LEDs), resistors, capacitors, inductors, transformers, and the like that may be packaged together into one cohesive structure that can be handled as a unit. For example, the semiconductor device may include one or more semiconductor dies (e.g., chips) assembled on a package substrate and encapsulated by a mold compound. The semiconductor device may be any suitable package type, such as ball grid array, chip-scale package, quad flat no-leads package (QFN), etc.

The term “thermal chamber” as used herein is a controlled environment enclosure designed to generate various temperature conditions for testing purposes. It typically includes an opening through which an object to be tested in placed inside the enclosure, means for closing the opening and thermally sealing it, means for changing the temperature within the enclosure in a controlled manner, and appropriate sensors for determining the actual temperature inside the enclosure. The enclosure is typically thermally insulated and sealed after it is closed. Heating and cooling systems are provided with the thermal chamber to accurately regulate the internal temperature of the enclosure over a desired range, from cold (e.g., −65° C., −55° C., −50° C., etc.) to high heat (e.g., 120° C., 125° C., 150° C., etc.).

The term “printed circuit board” as used herein is a mechanical support and electrical connection platform for electronic components. It is a generally flat board made of non-conductive material (e.g., fiberglass, epoxy resin, FR4 glass epoxy, etc.) with conductive pathways (also called traces) etched or printed onto its surface to connect different electronic components mounted on (i.e., affixed to) the board. The electronic components include resistors, capacitors, integrated circuits (ICs), connectors, and other active or passive devices. These components may be soldered onto (and/or otherwise securely attached to) the printed circuit board and interconnected by conductive traces within the board. The printed circuit board may have multiple layers of conductive traces separated by insulating layers. The number of layers varies according to the complexity of the circuit design and density of electronic components desired. The printed circuit board specifically excludes flexible cables and high temperature test lead wires.

The term “microcontroller” as used herein encompasses any IC capable of storing and executing instructions to perform computing tasks. It includes application specific ICs as well as general purpose microprocessors within the context of this disclosure. As used herein, the microcontroller receives electrical signals, processes them using suitable algorithms and embedded logic, and generates output signals that may be used variously, for example, to control other components; to generate an output on a user interface; to trim semiconductor devices; etc. The microcontroller may be a standalone device, for example, a programmable logic controller (PLC) or a dedicated microprocessor, or it may be embedded in other components. The microcontroller may be integrated with on-chip peripherals and memory in some embodiments, whereas in other embodiments, it may require external components for most functions beyond processing.

The term “connector” as used herein refers to a component that facilitates physical connection and electrical connectivity between a printed circuit board and external components, circuits, or systems. Connectors establish interfaces that enable communication, power transfer, signal transmission, and/or mechanical attachment with the printed circuit board. The connector as used herein specifically excludes cables and high temperature lead-wires. The connector is typically mounted on the printed circuit board either permanently (e.g., soldered) or removably (e.g., with screws or nuts and bolts). Examples of connectors include pin headers (e.g., pins that plug into holes in socket connectors), socket connectors (e.g., holes that mate with pin headers), surface-mount connectors (e.g., pins or balls that make conductive contacts with pads on the printed circuit board and/or the mating component), and edge connectors located along the edge of the printed circuit board.

The term “analog signal” as used herein includes any non-discrete continuously time-varying electromagnetic signal communicated through a wired medium, such as a conductive trace, conductive wire, conductive cable, etc. In some embodiments, the analog signal as used herein may have one or more frequencies in a range between 1 Hz and 1 GHz. Analog signals are often represented as waveforms, which are plots of voltage versus time. The shape of the waveform can provide information about the signal's frequency content and other characteristics. The voltage of the analog signal represents the strength or intensity of the signal. The frequency of the analog signal represents rate of change of the signal strength and is typically measured as the number of cycles per second. The phase of the analog signal represents the position of the signal's waveform relative to a reference point in time and is a characteristic of timing of the signal.

The term “connected” means a direct connection (which may be one or more of a communication, mechanical, and/or electrical connection) between the things that are connected, without any intermediary devices, while the term “coupled” means either a direct connection between the things that are connected, or an indirect connection through one or more passive or active intermediary devices.

The term “computing device” means a server, a desktop computer, a laptop computer, a smartphone, or any device with a microprocessor, such as a central processing unit (CPU), general processing unit (GPU), or other such electronic component capable of executing processes of a software algorithm (such as a software program, code, application, macro, etc.). The term also includes peripherals such as printer, user interface, screen, etc. that are coupled to the server, computer, and other such devices.

The description uses the phrases “in an embodiment” or “in embodiments,” which may each refer to one or more of the same or different embodiments.

Although certain elements may be referred to in the singular herein, such elements may include multiple sub-elements. For example, “a controller” may include one or more controllers.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale. In the drawings, same reference numerals refer to the same or analogous elements shown so that, unless stated otherwise, explanations of an element with a given reference numeral provided in context of one of the drawings are applicable to other drawings where element with the same reference numerals may be illustrated. Further, the singular and plural forms of the labels may be used with reference numerals to denote a single one and multiple ones respectively of the same or analogous type, species, or class of element.

Note that in the figures, various components are shown as aligned, adjacent, or physically proximate merely for ease of illustration; in actuality, some or all of them may be spatially distant from each other. In addition, there may be other components, such as wires, cables, hoses, fasteners, cable carriers, energy chains, routers, switches, antennas, communication devices, etc. and features such as cable ties, holes, recesses, openings, rails, etc. in the systems and networks disclosed that are not shown in the figures to prevent cluttering. Systems and networks described herein may include, in addition to the elements described, other components and services, including communication interfaces, microprocessors, microcontrollers, network management and access software, connectivity services, routing services, firewall services, content delivery networks, virtual private networks, etc. Further, the figures are intended to show relative arrangements of the components within their systems, and, in general, such systems may include other components that are not illustrated (e.g., various mechanical components and electronic components related to handling functionality, electrical connectivity, thermal stability, etc.).

In the drawings, a particular number and arrangement of structures and components are presented for illustrative purposes and any desired number or arrangement of such structures and components may be present in various embodiments. Further, unless otherwise specified, the structures shown in the figures may take any suitable form or shape according to various design considerations, manufacturing processes, and other criteria beyond the scope of the present disclosure.

For convenience, if a collection of reference numerals designated with different letters are present (e.g., 206a, 206b), such a collection may be referred to herein without the letters (e.g., as “206”) and individual ones in the collection may be referred to herein with the letters. Further, labels in upper case in the figures (e.g., 206A) may be written using lower case in the description herein (e.g., 206a) and should be construed as referring to the same elements.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Frequency trimming is used to adjust the operating frequency of an IC, i.e., a device under test (DUT), to match a specified target frequency. As used herein, the DUT is a semiconductor device that is being tested for its signal frequency (i.e., the frequency of at least one of its output signals is being measured). The DUT may be designed for the target frequency according to the device specifications, but the actual value may differ due to manufacturing variations, temperature effects, or other factors that could affect the frequency. Typically, frequency trimming is performed by first measuring the target frequency of the DUT. The frequency may be adjusted after measurement by various methods, such as changing passive components around the circuit generating the signal; using laser trimming techniques to adjust physical dimensions of the capacitors or resistors in the DUT; etc. The frequency may be measured again after this adjusting process and compared with the target frequency. If the target frequency is not met within the desired error or accuracy, the adjusting may be repeated, and the process continued iteratively until the desired target frequency is reached.

An important step in the trimming process is the accurate measurement of the frequency of the DUT. When the signal is a periodic signal, such as a clock signal having a sine wave pattern in time, a typical technique involves using frequency counters. Examples of other types of periodic waves are pulse wave, or square waves. The frequency counters count the number of times a rising edge or the falling edge of the periodic wave is encountered within a predetermined time interval, called gate time. The gate time is typically set by a time base of the frequency counter, which can be adjusted or selected based on the frequency range and desired resolution of the measurement. The time base setting affects how often the frequency counter samples the signal and calculates the frequency, influencing both the accuracy and speed of measurement. The longer it takes to count, i.e., the larger the gate time, the greater the accuracy of the frequency measurement. However, the longer it takes to count, the costlier it is to test the DUT, as expensive equipment are used for longer time for measuring. In addition, to ensure accuracy with frequency counters, only a few DUTs can be tested in parallel. Besides, the testing circuit for each DUT takes up a large area on a printed circuit board, making it cost prohibitive to test more than the few DUTs at a time.

Frequency counters are also prone to errors, such as drifting; resolution error; temperature induced error; etc. Longer time intervals to measure frequency can provide better accuracy but can introduce errors due to changes in the frequency of the signal during the time interval. Shorter time intervals reduce such drift but may lead to higher uncertainty in the count. If the frequency of the DUT signal falls close to the resolution limit of the frequency counter, the measurement may be less accurate. The frequency counter's internal oscillator may degrade over time, affecting its accuracy. Frequency counters may drift or exhibit changes in performance as ambient temperature varies, impacting measurement accuracy. Various other sources of error may also affect the measurement by the frequency counter.

Typically, accuracy of measurements by the frequency counter is represented as parts per unit, such as parts per million (ppm), parts per billion (ppb), or parts per trillion (ppt), each part in this scenario of frequency measurement referring to a cycle. Note that accuracy is the degree of conformity of a measured value to its target. With frequency counters, the smallest error (i.e., greatest accuracy) possible is to miss or spuriously count 1 cycle within the gate time. In one example, to measure a clock signal with a frequency of 1 MHZ (i.e., 10⁶ cycles per second) with 1 ppm accuracy may require a gate time of 1 second. To measure the same signal with 1 ppb accuracy may require a gate time of 1000 seconds, or approximately 16 minutes. Conversely, another signal having a frequency of 1 GHz may be measured with 1 ppb accuracy within a gate time of 1 second. Thus, the gate time, the measurement accuracy, and the frequency are interlinked when using frequency counters.

Frequency counters in the past used a digital gate method, which was easy to implement but the measurement accuracy depended on the frequency of the DUT signal. Modern frequency counters use a reciprocal counting method, in which the gate time is synchronous with the input signal, so the measurement error varies with the clock used to compare or measure the DUT signal. With such a technique, selecting a higher resolution reference clock and increasing gate time leads to improved measurement accuracy provided that an accurate time base is used. For better resolution, the reference frequency is multiplied to a reasonably high number. Some frequency counters may take additional measurements within the gate time and use this information to improve measurement accuracy.

Some advanced frequency measurement systems use phase comparisons between the DUT signal and the reference signal. The counter starts counting using the DUT signal and stops counting based on the reference signal. The frequency offset of the DUT signal from the reference signal is then calculated as the change in time interval divided by the gate time. When the DUT signal frequency has a short period, such as 100 ns in the case of 10 MHZ, keeping track of cycles during such a phase comparison is difficult. Therefore, phase comparisons normally test low frequencies with long periods, such as 1 or 10 Hz. The low frequency is obtained by dividing the DUT signal frequency, or by mixing it with another frequency to a lower frequency. Dividers are typically more versatile but may have lower accuracy than mixers.

A mixer is a three-port component, which typically performs the task of frequency conversion, translating the frequency of an input signal to a different frequency. An ideal mixer produces an output that consists of the sum and difference in frequencies of its two input signals. In other words: fₒᵤₜ=fᵢₙ₁±fᵢₙ₂, where fₒᵤₜ is the frequency of the output signal from the mixer, and fᵢₙ₁ and fᵢₙ₂ are the frequencies of the input signals. When the mixer is performing up-conversion, the output signal has a frequency which is the sum of the input frequencies; when the mixer is performing down-conversion, the output frequency is the difference between the input frequencies. Whether the mixer performs up-conversion or down-conversion depends on the mixer's ports to which the inputs are connected. When used in frequency measurements, the mixer is used in a down-conversion mode, with the output frequency of the mixer being lower than that of the input DUT signal. Mixer systems in measurement scenarios are typically expensive, requiring dedicated hardware including a reference oscillator for the mixer. When used with a frequency counter, which requires its own reference oscillator for its time base, the hardware for the mixer-frequency counter combination can get expensive in terms of the component cost and the area or space occupied by the test components on a printed circuit board or testing floor.

Other factors that affect the measurement accuracy include the length of the conductive traces connecting the DUT to the reference clock and other components used in the measurement circuit. The shorter the conductive traces, the better the measurement accuracy. Thus, the placement of the measurement components around the DUT affects the evaluation of the frequency of the DUT signal.

Modern frequency counters may not be effective in measuring frequency with the accuracy that current semiconductor technology and manufacturing cost constraints demand. Currently available frequency counters, such as Keysight™ Frequency Counter, can measure frequency at ppb levels in about 1 sec. But these counters use many different techniques involving complex electronic components to get such level of accuracy, which leads to expensive test equipment. To do parallel frequency measurements with such frequency counters would require many such frequency counters, which makes for prohibitive costs. Therefore, there is a need to improve current techniques for measuring signal frequency of a semiconductor device to obtain higher accuracy at lower cost.

In addition, temperatures typically affect the frequency of the signals. In other words, when the DUT is heated or cooled, the DUT signal frequency could change correspondingly. This change of frequency with temperature is typically measured and characterized by testing the DUT inside a thermal chamber. Such testing typically involves placing the DUT inside the thermal chamber, connecting it using high temperature sockets to high temperature lead-wires that extend to a measurement system outside the thermal chamber and then changing the temperature of the thermal chamber appropriately while measuring the DUT signal frequency. In such systems, the high temperature lead-wires and sockets are expensive because they must be reliable over many heating and cooling cycles. The high temperature lead-wires also place the measurement components far from the DUT, thereby impacting the accuracy of the measurements.

Accordingly, systems and methods are disclosed herein that enable massively parallel trimming of semiconductor devices across a temperature range with accuracy approximately in the order of one to hundred parts per trillion. In one embodiment, the method involves mixing the DUT signal with a reference signal from a local oscillator (LO) having the target frequency, thereby down-converting the DUT signal to a lower frequency, filtering the down-converted signal to attenuate higher frequencies, digitizing the filtered down-converted signal into digital samples and then analyzing the digital samples. The analysis of the digital samples involves windowing the samples within a suitable frequency window, computing a discrete frequency spectrum using a Fast Fourier Transform (FFT) algorithm within the frequency window, and then fitting an interpolating function on consecutive frequency bins in the discrete frequency spectrum to evaluate the frequency of the DUT signal with very high accuracy. After evaluation, the DUT may be trimmed suitably to match the target frequency.

Windowing, followed by FFT, followed by fitting an interpolating function is typically used in performing spectral analysis of signals having multiple frequencies. The signals that are typically measured using this technique contain numerous frequencies with different magnitudes, such as are typically encountered with radio frequency signals in communication systems, signal processing, and vibration analysis. FFT is thus not used with frequency counters as it is more appropriate for spectral analysis over a range of frequencies. In addition, FFT sacrifices time resolution for frequency resolution, meaning it is typically not suitable for measuring exact instantaneous frequencies within a short time interval. FFT generally requires longer data acquisition periods than frequency counters to accumulate enough samples for accurate analysis, making it less suitable for real-time frequency measurement applications. However, in various embodiments described herein, FFT may be used judiciously to enable highly accurate measurements of the DUT signal frequency. Experimental validation has shown results with accuracy of approximately 24-30 ppt with standard deviation of approximately 1.5 ppt.

In some embodiments, many DUTs may be mounted on printed circuit boards and placed inside a thermal chamber. The printed circuit boards may be directly removably attached using a suitable connector (e.g., thermally reliable, cost-effective, electrically well performing, etc.) such as a pogo pin connector, to other printed circuit boards. These other printed circuit boards may extend out of the thermal chamber through thermally sealed slots. The electronic circuits and components to test the DUTs may be mounted or coupled to these printed circuit boards outside the thermal chamber. In such a configuration, the electronic components to test the DUT may be located close to the DUT and yet shielded from the temperature changes inside the thermal chamber, unlike in machines that use high temperature lead-wires or sockets. Such a system may enable modularized, massively parallel trimming of many DUTs across a range of temperature with higher accuracy and faster throughput than is possible using frequency counters.

### EXAMPLE EMBODIMENTS

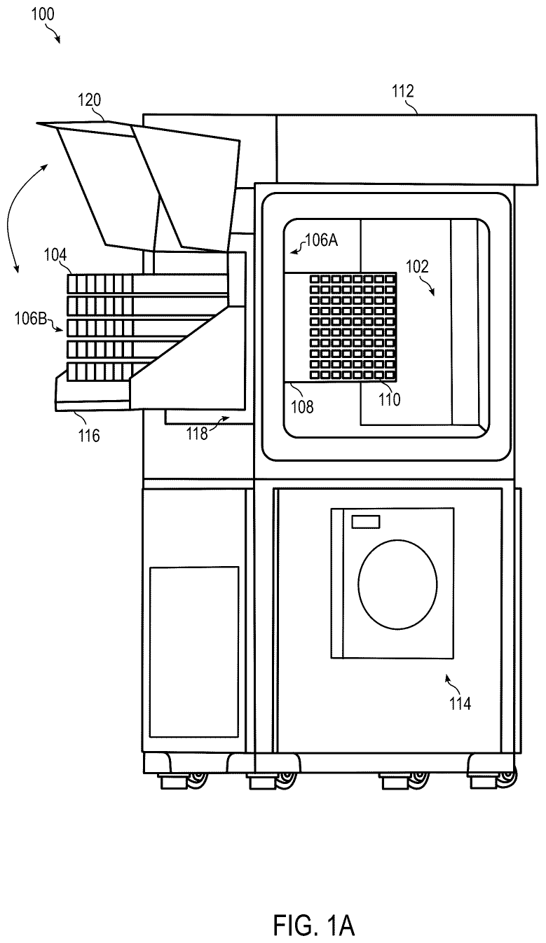

FIGS. 1A-1D are simplified diagrams illustrating a system 100 for enabling massively parallel trimming of semiconductor devices according to an example embodiment. As shown in the perspective view illustrated in FIG. 1A, system 100 includes a thermal chamber 102. A measurement board 104 has a portion 106a (not visible in the view shown) inside thermal chamber 102 and another portion 106b outside thermal chamber 102. In various embodiments, measurement board 104 comprises a rigid printed circuit board. A test board 108 may be removably coupled to portion 106a of measurement board 104 inside thermal chamber 102. In various embodiments, test board 108 comprises another rigid printed circuit board. One or more of DUT 110 is affixed to test board 108, for example, by soldering, in sockets, etc. In some embodiments, DUT 110 may be any type of semiconductor device, such as a microprocessor, a communications chip, etc.; in some example embodiments, DUT 110 may comprise a micro-electro-mechanical system (MEMS) oscillator. In various embodiments, DUT 110 may generate an analog signal having a frequency between 1 Hz and 1 GHz. For example, DUT 110 may generate an analog signal having a frequency of 60 MHz; in another example, DUT 110 may generate an analog signal having a frequency of 725 MHz; and so on. The signal generated by DUT 110 may be called herein as a “measurement signal.” In various embodiments, many ones of measurement board 104 and test board 108 may be provisioned in system 100 as described further below.

Thermal chamber 102 may be part of an oven 112, configured with suitable systems 114 (not visible) such as heating and cooling systems and control systems, to regulate the temperature inside thermal chamber 102 according to particular needs. For example, the temperature inside thermal chamber 102 may be cycled multiple times between a minimum temperature (e.g., −55° C.) and a maximum temperature (e.g., 150° C.) according to a predetermined cycling rate while DUT 110 is tested. In another example, the temperature inside thermal chamber 102 may be maintained at a specific temperature (e.g., −50° C. or 125° C.) for a predetermined time period while DUT 110 is tested. Any suitable technique to achieve such temperature variation inside thermal chamber 102 may be employed without departing from the scope of the embodiments disclosed herein.

Oven 112 may have a lidded casing 116 removably attached to a side 118 of thermal chamber 102. Lidded casing 116 may be attached to side 118 using any suitable means, such as fasteners, nuts and bolts, etc. Lidded casing 116 may include a lid 120, which can be opened and closed as desired. In the embodiment shown, lid 120 is hinged such that it is rotatable around an axis. In other embodiments, lid 120 may be removable, slidable or openable in other ways. Portion 106b of measurement board 104 may be supported and housed (e.g., enclosed) within lidded casing 116. In various embodiments, lidded casing 116 may be configured for air flow circulation to enable measurement board 104 to be maintained at ambient room temperature when thermal chamber 102 is at a different temperature. Lidded casing 116 may also include openings (not visible) for wires, cables, etc. that enable electrical connectivity of measurement board 104 to other components, such as a computing device (not shown).

A detail of a portion of thermal chamber 102 is shown in the perspective view illustrated in FIG. 1B. Test board 108 and DUT 110 are not shown in FIG. 1B. In this view, portion 106a of measurement board 104 is visible in thermal chamber 102. Portion 106a may include a connector 122 affixed thereto. Connector 122 may enable removably coupling measurement board 104 to test board 108 inside thermal chamber 102. In the embodiment shown, measurement board 104 may pass through a slot 124. In some embodiments, many ones of measurement board 104 may extend into thermal chamber 102 through a single one of slot 124. In other embodiments, each measurement board 104 may extend into thermal chamber 102 through a separate one of slot 124.

A detail of an example arrangement of many ones of measurement board 104 is shown in FIG. 1C. The many one of measurement board 104 may be arranged in an array of horizontal rows 126 and vertical columns 128. Each measurement board 104 may include one or more of electronic circuits 130. In the embodiment shown, some of electronic circuits 130 may be embodied as mounted electronic components on measurement board 104. Such electronic components may be mounted only on one side of measurement board 104 in some embodiments (not shown). In other embodiments (as shown), the electronic components may be mounted on either side of measurement board 104. The electronic components may be affixed to measurement board 104 through any suitable means, such as soldering, mounted in sockets, etc. within the broad scope of the embodiments. Not all rows 126 and columns 128 may be filled with measurement board 104 in some embodiments. In an example embodiment, each measurement board 104 may be used to measure 16 DUT 110. System 100 may accommodate 5 rows and 8 columns of measurement board 104 so that system 100 may be capable of measuring and trimming up to 16×5×8=640 DUTs 110. Note that any number of rows, columns and DUTs per measurement board 104 may be used without departing from the scope of the embodiments.

A detail of another example arrangement of many ones of measurement board 104 is shown in FIG. 1D. The many ones of measurement board 104 may be arranged in an array of vertical columns 128. Not all columns 128 may be filled with measurement board 104 in some embodiments.

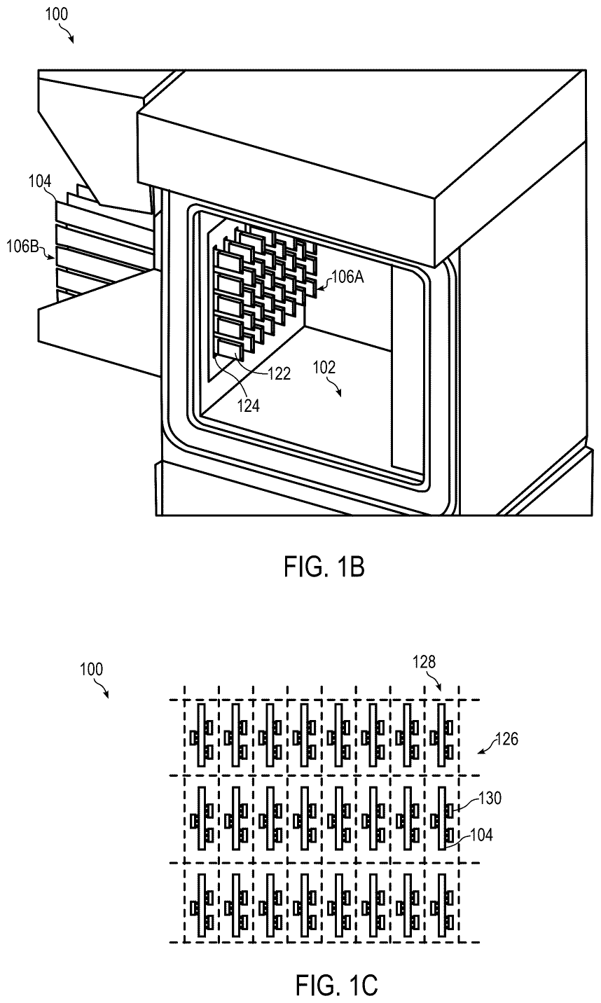

FIG. 2 is a simplified diagram illustrating an example connector 122 for enabling electrical and physical connection between measurement board 104 and test board 108 according to an example embodiment. In the example shown, connector 122 is a double-sided spring-loaded pogo-pin connector. It comprises a rigid board 132 in which are positioned many ones of conductive spring-loaded pins 134. In various embodiments, measurement board 104 may be provisioned with conductive pads or plated through-holes to which pins 134 may make conductive contact when 122 is affixed to measurement board 104.

In some embodiments, connector 122 may be removably connected to measurement board 104. In some such embodiments, a plurality of fastener holes 136 may be provided to enable fastening to measurement board 104 using appropriate fastening mechanisms such as screws or other threaded fasteners. Another plurality of alignment holes 138 may be provided to enable accurate alignment of connector 122 on measurement board 104. In some such embodiments, when connector 122 is assembled to measurement board 104, springs in plurality of conductive spring-loaded pins 134 proximate to measurement board 104 may compress to ensure conductive contact between connector 122 and measurement board 104. In some other embodiments (not shown), connector 122 may be permanently affixed to measurement board 104, for example, by soldering or brazing plurality of conductive spring-loaded pins 134 to corresponding pads or vias in measurement board 104. In some such embodiments, plurality of conductive spring-loaded pins 134 may be spring-loaded on only one side opposite to measurement board 104. In yet other embodiments, connector 122 may comprise conductive holes configured to mate with pins on a corresponding connector in test board 108. Various other connectors and connector configurations that facilitate electrical and physical connectivity between measurement board 104 and test board 108 may be implemented in system 100 without departing from the scope of the embodiments.

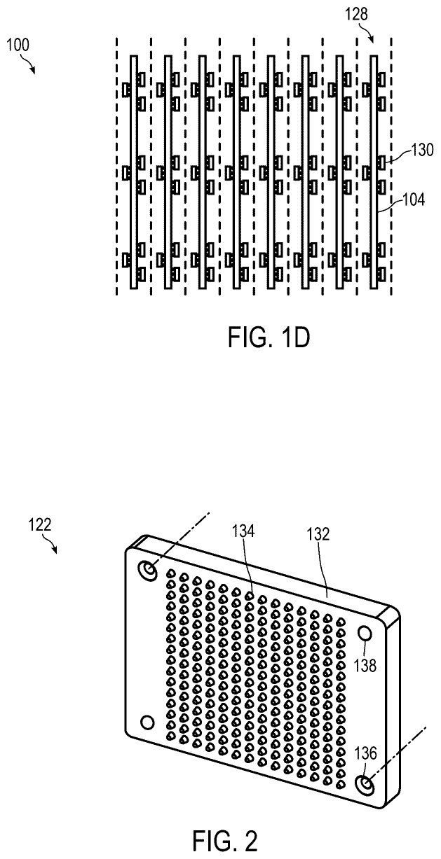

FIG. 3 is a simplified diagram showing an example embodiment of system 100. In the example shown, measurement board 104 may be electrically and physically coupled with connector 122 to test board 108. Test board 108 may have many ones of DUT 110 affixed thereto. Test board 108 may be electrically and physically coupled to more than one measurement board 104 in the example shown. In some such cases, a subset of the many ones of DUT 110 may be electrically coupled to one of measurement board 104. For example, two rows of DUT 110, shown shaded in the view, may be electrically coupled to measurement board 104. Measurement board 104 may include three separate portions 106: first portion 106a inside thermal chamber 102; second portion 106b outside thermal chamber 102; and a third portion 106c between 106a and 106b that is located within slot 124.

Thermal chamber 102 may be enclosed by a wall 302, and slot 124 may be thermally insulated from the ambient environment outside thermal chamber 102 by insulation 304. Wall 302 may be part of oven 112, and may comprise metallic materials, ceramic materials, and other suitable materials that serve to demarcate thermal chamber 102 structurally and thermally from the external environment. Although wall 302 is shown as being made of one layer or material, in various embodiments, wall 302 may include any number and type of materials or layers without departing from the scope of the embodiments. Insulation 304 may comprise any suitable thermal insulation, such as fiberglass, cellulose, foam board, mineral wool, etc. In various embodiments, insulation 304 may serve to prevent air leaking out of thermal chamber 102 through slot 124.

In the example shown, measurement board 104 is a contiguous board extending from inside thermal chamber 102 to outside oven 112. In some other embodiments (not shown), measurement board 104 may include two (or more) discrete pieces, connected at suitable locations, for example, the boundary between insulation 304 and the ambient outside environment, or the boundary between wall 302 and thermal chamber 102. The connection may be enabled in such embodiments with a suitable connector, such as an edge connector.

Measurement board 104 may include one or more of electronic circuits 130 that are electrically coupled to DUT 110 by conductive traces 308 in measurement board 104. In various embodiments, electronic circuits 130 comprise at least one each of: a mixer circuit, a low pass filter circuit, an analog-to-digital converter circuit, and a microcontroller circuit. In the example shown, each of DUT 110 may be electrically coupled to a separate one of electronic circuits 130. For example, DUT 110a may be electrically coupled to electronic circuits 130a; DUT 110b may be electrically coupled to electronic circuits 130b. Each one of electronic circuits 130, for example, 130a 130b may comprise separate ones of the mixer circuit, the low pass filter circuit, the analog-to-digital converter circuit, and the microcontroller circuit in some embodiments. In another embodiment, the microcontroller circuit (or any one or more of the other named circuits) may be shared among more than one of DUT 110.

In some such embodiments, the size of measurement board 104 may be associated with the number of electronic circuits 130 that can be accommodated thereon for each separate one of DUT 110. Conversely, the number of DUT 110 that can be electrically coupled to a single one of measurement board 104 may depend on the size or available area for electronic circuits 130. In the example shown, a subset 310 of the total number of DUT 110 in test board 108 may be conductively coupled to measurement board 104. Other such ones of subset 310 may be conductively coupled to corresponding other ones of measurement board 104. In various embodiments, portion 106C of measurement board 104 within slot 124 may not have any electronic components thereon, except for conductive traces 308.

Measurement board 104 may be electrically coupled to one or more of a local oscillator (LO) 312 and a computing device 314. Computing device 314 may enable communicating with DUT 110 or electronic circuits 130 suitably. LO 312 may generate a reference signal at a known frequency in various embodiments. Any suitable oscillator may be used as LO 312 within the broad scope of the embodiments.

During operation, a measurement signal may be received at the mixer circuit in electronic circuits 130 from DUT 110. The measurement signal may have an unknown frequency that must be measured by system 100. A reference signal having a known frequency may be received at the mixer circuit from LO 312. In some embodiments, the unknown frequency of the measurement signal (e.g., 60.00001 Hz) may be approximately close to the known frequency of the reference signal (e.g., 60 Hz). In some embodiments, the differential between the unknown frequency and the known frequency may be of the order of 1 ppb or smaller. In some embodiments, a known offset frequency (e.g., 100 Hz) may be added to the expected target frequency of the measurement signal (e.g., 60 Hz) to generate the known frequency of the reference signal. The known offset frequency may serve to enhance the differential between the unknown frequency and the known frequency, which may lead to better measurement resolution. The mixer circuit may mix the measurement signal and the reference signal to generate a mixed output signal, which may be passed through the low pass filter circuit to remove frequencies above a predetermined threshold, for example, 100 Hz. The predetermined threshold may be configured according to the frequency differential expected between the measurement signal and the reference signal. In one example embodiment, the predetermined threshold may attenuate all frequencies above 100 Hz. The filtered signal may be digitized by the analog-to-digital converter into a plurality of digital signal samples.

The digital signal samples may then be processed by the microcontroller circuit, which may be programmed with a windowing algorithm, an FFT algorithm, and a fitting algorithm. In an example embodiment, the windowing algorithm limits the digital signal samples within a Gaussian window. Other windows may be used within the broad scope of the embodiments. The windowed samples are analyzed by the FFT algorithm to generate a discrete spectrum of the digital signal samples in the frequency domain. The discrete spectrum consists of several frequency bins within the frequency window. The fitting algorithm then fits a plurality (e.g., three) consecutive frequency bins to an interpolating function. In an example embodiment, the fitting algorithm is a parabolic function. In another embodiment, the interpolating function is a Gaussian function. The best fit to the apex of the interpolating function is determined and returned as the value of the unknown frequency of the measurement signal. In other embodiments in which other types of interpolating functions are used, the corresponding suitable best fit is determined and returned accordingly. Based on this evaluated frequency, DUT 110 may be suitably trimmed. The process may be repeated until the desired frequency of the measurement signal is obtained.

In various embodiments, several ones of DUT 110 may be tested and trimmed in parallel in system 100, enabling high throughput without loss of accuracy. A modular approach with multiple ones of measurement board 104 coupled to test board 108 enables tailoring the number of DUT 110 to be tested according to individual preferences and/or other constraints. With a setup as shown in various examples herein, experiments indicate that the measurement accuracy of system 100 is in the order of 24 ppt with a standard deviation of 1.5, which is an improvement over a frequency counter, which gave a measurement accuracy of 16.7 ppt with a standard deviation of 32.7. In addition, the massively parallel and modular setup enables higher throughput than is possible with current frequency counter techniques. Thus, system 100 may facilitate cost-effective, accurate and stable measurement of frequency of semiconductor device signals.

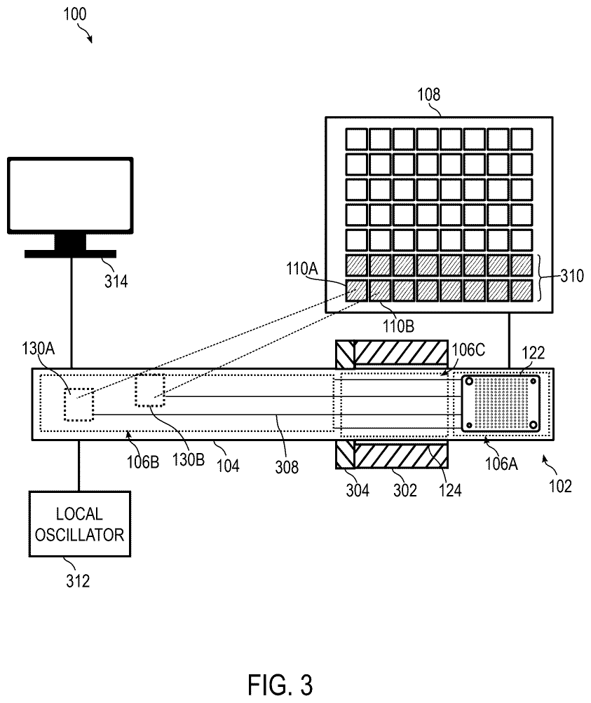

FIG. 4 is a simplified block diagram illustrating example electronic circuits 130 of system 100, according to an example embodiment. A measurement signal 402 having an unknown frequency f₁ from DUT 110 (not shown) and a reference signal 404 having a known frequency f₂ from LO 312 (not shown) may be mixed at a mixer circuit 406. In various embodiments, measurement signal 402 and reference signal 404 are analog signals. In some embodiments, mixer circuit 406 may comprise a multiplier circuit. In some embodiments, mixer circuit 406 may also comprise suitable buffer circuits (e.g., separately for measurement signal 402 and reference signal 404). Output signal 408 from mixer circuit 406 may have a frequency Δf approximately equal to the difference between the unknown frequency f₁ of measurement signal 402 and the known frequency f₂ of reference signal 404 (i.e., Δf=f₂−f₁). In other words, measurement signal 402 may be downconverted using mixer circuit 406. Additional noise components with higher or lower frequencies may also be present in output signal 408. Output signal 408 may be passed through a low pass filter circuit (LPF) 510 configured to attenuate frequencies higher than a preconfigured threshold. Filtered signal 412 from LPF 410 may have a frequency approximately equal to Δf, with higher frequency components removed or significantly attenuated.

In some embodiments, the known frequency f₂ may be the expected target frequency f₀ of measurement signal 402 (i.e., f₂=f₀) and unknown frequency f₁ may vary from the expected target frequency f₀ by a differential δf of the order of 1 ppb or smaller (i.e., f₁=f₀±δf, δf≤1 ppb). In such embodiments, the downconversion with mixer circuit 406 may result in output signal 408 having an extremely low frequency Δf, for example, of the order of 1×10⁻⁹ Hz (i.e., Δf=±δf≤1×10⁻⁹). In such a case, the measuring technique must have a resolution finer than 1 ppb; this implies the number of samples must be large, or the time of measurement must be long. Accordingly, in some other embodiments, a known offset frequency f_{off} may be added to the expected target frequency f₀ to generate the known frequency f₂ of the reference signal (i.e., f₂=f₀+f_{off}). In some such embodiments, Δf may be of the order of the offset frequency f_{off}, serving to enhance measurement resolution (i.e., Δf=f₂−f₁=(f₀+f_{off})−(f₀±δf)=f_{off}±δf). In one example, the measurement resolution may be improved by three orders of magnitude using offset frequency f_{off} of 100 Hz.

Filtered signal 412 from LPF 410 may be passed through an analog-to-digital converter (ADC) 514 to generate digital signal 416. In various embodiments, ADC 414 may be a stand-alone digitizer; in other embodiments, ADC 414 may be a discrete IC mounted (e.g., soldered) on measurement board 104. In yet other embodiments, ADC 414 may be incorporated into a larger electronic component that includes other functionalities and is mounted on measurement board 104. A windowing module 418 may limit a frequency window of digital signal 416 according to a windowing function 420. In various embodiments, windowing is performed by multiplying digital signal 416 with a signal having a waveform following windowing function 420. Windowing function 420 may be zero-valued outside the frequency window so that further analysis of windowed signal 422 from windowing module 418 may be confined to the frequency window. Windowing also reduces (e.g., tapers to zero) the amplitude of any discontinuities at the boundaries (e.g., edges) of the frequency window.

The frequency characteristic of windowing function 420 is a continuous spectrum with a main lobe and several side lobes. The main lobe is centered at each frequency component of the time-domain signal, and the side lobes approach zero. The height of the side lobes indicates the affect windowing function 420 has on frequencies around main lobes. In various embodiments, windowing function 420 may be chosen according to the waveform and characteristics expected of measurement signal 402 and/or digital signal 416. For example, if digital signal 416 contains strong interfering frequency components distant from the frequency of interest, a smoothing window with a high side lobe roll-off rate may be selected for windowing function 420. If digital signal 416 contains strong interfering signals near the frequency of interest, windowing function 420 may be chosen with a low maximum side lobe level. If the frequency of interest contains two or more signals very near to each other, windowing function 420 having a very narrow main lobe may be selected. Various other selections may be made as appropriate and based on particular needs. Examples of windowing function 420 include rectangular window (e.g., Boxcar, Dirichlet), B-spline window (e.g., polynomial), Welch window, sine window, Hann window, Hamming window, Blackman window, etc. In an example embodiment windowing function 420 may be selected to be a Gaussian window. In another example embodiment windowing function 420 may be selected to be a Blackman-Harris-Nuttall (BHN) window.

Windowed signal 422 may be transformed into frequency domain an FFT algorithm 424 to generate a discrete spectrum 426. Discrete spectrum 426 may include a plurality of frequency bins within the frequency window. A fitting algorithm 428 may identify the biggest frequency bin kₘ within discrete spectrum 426. The biggest frequency bin kₘ has the highest power amplitude in discrete spectrum 426. An interpolating function 430 may be fitted to a plurality of at least three consecutive frequency bins symmetrical around this largest frequency bin kₘ. In other words, the smallest set of consecutive frequency bins includes frequency bins kₘ, kₘ₋₁ and kₘ₊₁. The best fit may be identified by a relatively low value of root mean square in some embodiments. In other embodiments, other error measures may be used without departing from the scope of the embodiments. The choice of the best fit algorithm, including the function or the type of error to use may depend on the speed of computation, the overall accuracy desired and other factors beyond the scope of the disclosure. In an example embodiment, interpolating function 430 may be a Gaussian function. In another embodiment, interpolating function 430 may be a parabolic function. Note that any other suitable function (e.g., trigonometric functions, Lorentzian functions, Voigt functions, polynomial functions, etc.) and number of consecutive frequency bins (e.g., 3, 4, 5, etc.) may be used according to the characteristics of discrete spectrum 426 within the broad scope of the embodiments herein. The apex of interpolating function 430 is the estimated value of unknown frequency f₁ and is returned as result 432. DUT 110 may then be trimmed according to result 432 by a trimming module 434.

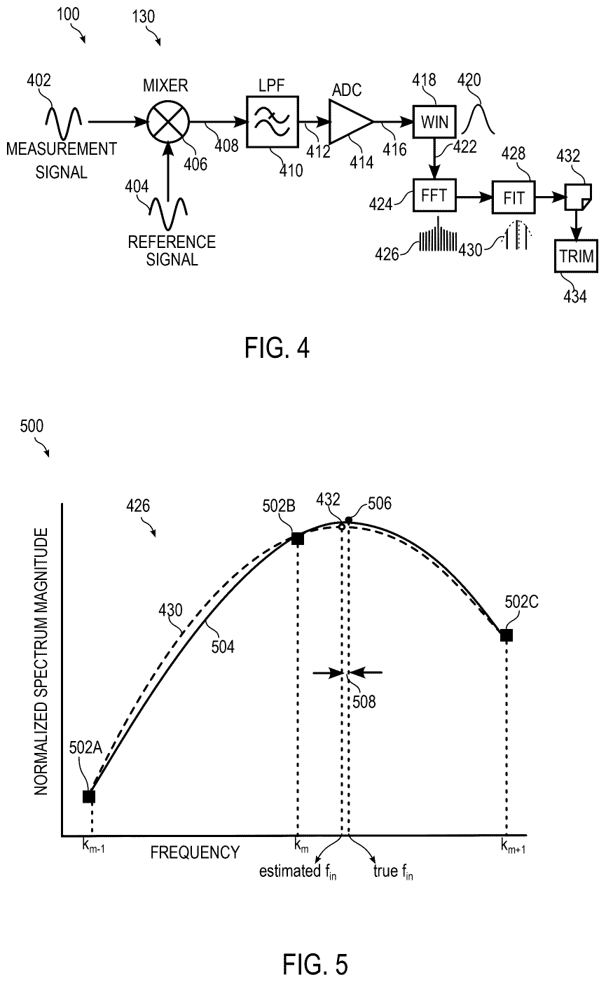

FIG. 5 illustrates certain interpolating techniques of system 100 in greater detail. Assume windowed signal 422 is a bandlimited compound signal s(t), which is to be uniformly sampled with frequency fₛ and contains a sinusoidal component sᵢₙ (t) whose frequency fᵢₙ is to be measured. The FFT magnitude spectrum S[k] of the sampled signal, computed by FFT algorithm 424, is given by:

$$S [ k ] = \vert {\sum }_{n = 0}^{N - 1} s [ n ] exp ( - j \frac{2 π nk}{N} ) \vert$$

where s[n] is the signal sample sequence in a sampling period of interest and N is the total number of samples. Discrete spectrum 426 is calculated at frequencies that are integer multiples of the ratio fₛ/N where fₛ is the frequency of the sampling period. When discrete magnitude spectrum S[k] has a local maximum corresponding to component sᵢₙ (t) at spectrum frequency bin kₘ, its frequency fᵢₙ can be approximated as:

$${f}_{in} ≅ \frac{{k}_{m}}{L}$$

where L is the sampling duration, i.e., the frequency window defined by windowing function 420. In general, kₘ is the index of the biggest frequency bin within the frequency window of interest. When fᵢₙ is located exactly on a local maximum peak of discrete spectrum 426 at bin kₘ, fᵢₙ can be evaluated with no error. Any discrepancy between fᵢₙ and the local maximum peak in discrete spectrum 426 results in error. This error can be minimized by fitting algorithm 428 using a suitable one of interpolating function 430 that best fits a plurality of consecutive frequency bins around kₘ, for example, between kₘ₋₁ and kₘ₊₁. Frequency fᵢₙ can then be estimated as the maximum abscissa of interpolating function 430 between kₘ₋₁ and kₘ₊₁. Such a technique requires at least three consecutive frequency bins within a range of interest. Such a three-node interpolation method, when used in conjunction with an appropriate window, can give improvements of frequency measurement resolution beyond three orders of magnitude.

Graph 500 illustrates the above-described fitting algorithm 428 in more detail. Frequency is represented on the horizontal axis and normalized spectrum magnitude on the vertical axis. Three consecutive frequency bins 502a, 502b and 502c in discrete spectrum 426 are represented by filled squares. Frequency bin 502a represents kₘ+1, frequency bin 502b represents kₘ and frequency bin 502c represents kₘ+1. As noted previously, kₘ is the biggest frequency bin in discrete spectrum 426. Solid line 504 represents the true normalized continuous spectrum of windowed signal 422 having three consecutive frequency bins 502a-502c. The apex of windowed signal 422 between frequency bins 502a-502c, which is the true fᵢₙ, is represented by filled dot 506. Both the true normalized continuous spectrum and the true fᵢₙ are unknown. The dashed line represents interpolating function 430. Note that where interpolating function 430 is the best fit to frequency bins 502a, 502b and 502c, the apex of interpolating function 430 is the estimated fᵢₙ, namely result 432, represented by an unfilled dot in graph 500. The difference between the true fᵢₙ and the estimated fᵢₙ constitutes interpolation error 508. Note that graph 500 represents a technique with three consecutive frequency bins 502a-502c; in other embodiments, more than three consecutive frequency bins may be used without departing from the scope of the embodiments.

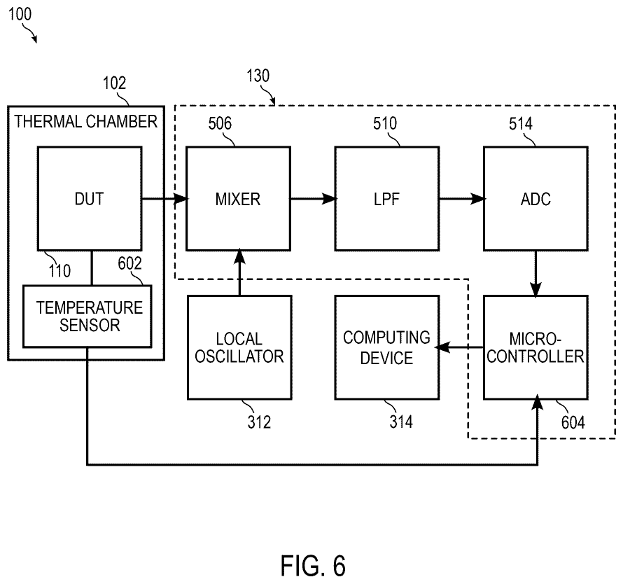

FIG. 6 is a simplified block diagram illustrating an example configuration of system 100, according to an embodiment. One or more temperature sensor 602 may be provisioned in thermal chamber 102. Temperature sensor 602 may be a thermocouple (or other suitable temperature sensor) attached to (or placed in) thermal chamber 102 in some embodiments. In other embodiments, temperature sensor 602 may be a sensor integrated into DUT 110. In yet other embodiments, the thermocouple may be attached to test board 108. In still other embodiments, temperature sensor 602 may include a combination of two or more of thermocouples in thermal chamber 102, thermocouples on test board 108 and integrated sensors in DUT 110.

Output pins of DUT 110 may be conductively coupled to one or more input pins of mixer circuit 406 by means of conductive traces 308 on measurement board 104. Another set of input pins of mixer circuit 406 may be coupled to LO 312 by conductive traces 308 and/or optional cables, wires, etc. as needed. One or more output pins of mixer circuit 406 may be conductively coupled to one or more input pins of LPF 410 by conductive traces 308. One or more output pins of LPF 410 may be conductively coupled to one or more input pins of ADC 414. In some embodiments, LPF 410 and ADC 414 may be separate components on measurement board 104, in which case, they may be conductively coupled by conductive traces 308. In other embodiments, LPF 410 and ADC 414 may be integrated into a semiconductor chip, in which case, the conductive coupling may be by on-chip traces.

One or more output pins of ADC 414 may be conductively coupled to one or more input pins of a microcontroller 604. Microcontroller 604 may be configured with windowing module 418, FFT algorithm 424 and fitting algorithm 428 in some embodiments. One or more output pins of microcontroller 604 may be conductively coupled to computing device 314. In various embodiments, temperature sensor 602 may also be conductively coupled to one or more input pins of microcontroller 604.

In various embodiments, as DUT 110 is cycled through, or subjected to various temperatures in thermal chamber 102. The temperatures may be sensed by temperature sensor 602 and logged by microcontroller 604 suitably, for example, to characterize the frequency variation of signals from DUT 110 under various temperatures. In some embodiments, the temperature measurements may be used to trigger other actions, such as changing from one of LO 312 to another of LO 312 based on the temperature, modulating the known frequency of reference signal 404 according to the temperature, etc.

In the embodiment shown, one of DUT 110 is coupled to a corresponding one of microcontroller 604. In some embodiments, more than one of DUT 110 may be coupled to one of microcontroller 604. Likewise, any number of temperature sensor 602 may be coupled to microcontroller 604 without departing from the scope of the embodiments.

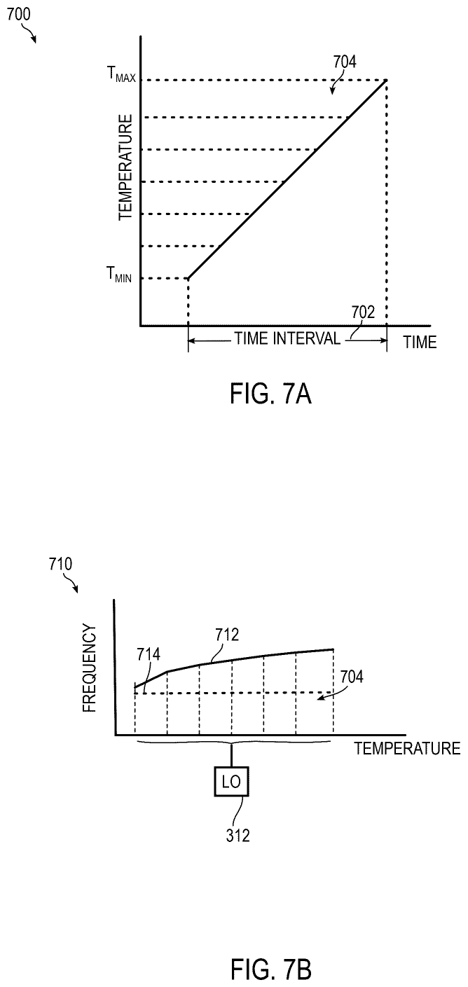

FIGS. 7A-7B are simplified diagrams showing temperature effects in system 100 according to certain embodiments. FIG. 7A shows a graph 700 plotting a linear change in temperature between a minimum temperature T_{MIN} and a maximum temperature T_{MAX} within a certain time interval 702. The temperature range between T_{MIN} and T_{MAX} may be subdivided into two or more temperature ranges 704. In FIG. 7B, the frequency variation with temperature is plotted in graph 710. Measurement signal 402 may have a frequency variation 712 as shown with varying frequencies in different temperature ranges, and LO 312 may have a substantially constant frequency shown by dotted line 714 in the desired temperate range between T_{MIN} and T_{MAX}. The frequency variation 712 may be captured with sufficient accuracy (e.g., in the order of ppb or ppt) with a judiciously selected frequency of LO 312 as shown by dotted line 714. For example, the frequency of LO 312 as depicted by dotted line 714 may be approximately an average expected value between a minimum frequency and a maximum frequency within frequency variation 712. In some other examples, the frequency of LO 312 may be approximately close to the minimum expected frequency within frequency variation 712. In some other examples, the frequency of LO 312 may be approximately close to the maximum expected frequency within frequency variation 712.

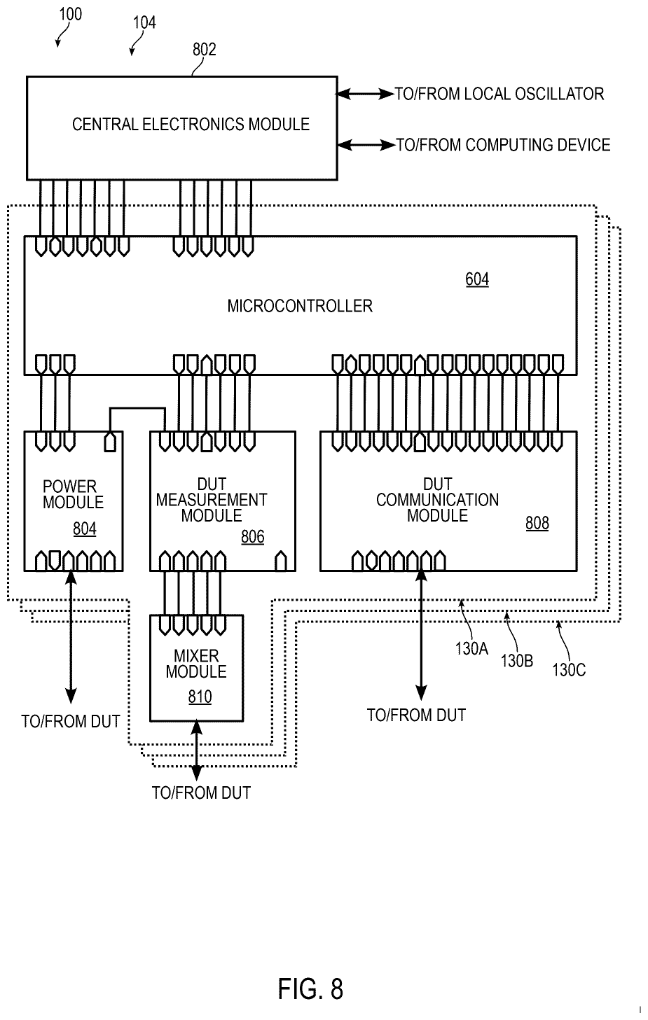

FIG. 8 is a simplified block diagram illustrating an example configuration of measurement board 104 in system 100 according to an example embodiment. Electronic circuits 130 associated with a plurality of DUTs 110 may be controlled by a central electronics module 802. For example, electronic circuits 130a, 130b and 130c are shown in the figure. More or less number of electronic circuits 130 may be included without departing from the scope of the embodiments. Any number of electronic circuits 130 may be controlled by central electronics module 802. In an example embodiment, 16 DUTs 110 are measured by one measurement board 104, which is provisioned with one central electronics module 802. 16 different instances of electronic circuits 130 may be provisioned in measurement board 104, each instance to measure a different one of DUT 110. Each instance of electronic circuits 130 may be addressable by central electronics module 802 using a different address or name. In one embodiment, an I2C protocol is used to communicate between central electronics module 802 and electronic circuits 130. In some such embodiments, each address may comprise 6 bits. For example, electronic circuits 130a may have a different address (i.e., different set of 6 bits) than electronic circuits 130b and electronic circuits 130c. Note that I2C protocol is merely provided as an example; any suitable communication protocol between central electronics module 802 and electronic circuits 130 is included within the broad scope of the embodiments. The addressing format may vary according to the communication protocol used.

Each one of electronic circuits 130 (e.g., 130A) may include microcontroller 604, a power module 804, a DUT measurement module 806, a DUT communication module 808 and a mixer module 810. In the example embodiment shown, only microcontroller 604 communicates with central electronics module 802 in electronic circuits 130A. In turn microcontroller 604 communicates with power module 804, DUT measurement module 806 and DUT communication module 808. In some embodiments (as shown), only DUT measurement module 806 communicates with mixer module 810; in other embodiments (not shown), power module 804 and DUT communication module 808 may also communicate with mixer module 810. Each of power module 804, mixer module 810 and DUT communication module 808 may communicate separately with DUT 110.

In various embodiments, central electronics module 802 includes a microcontroller having sufficient storage, processing capability and input/output to communicate with electronic circuits 130, LO 312 and computing device 314. In various embodiments, multiple instances of microcontroller 604 may be suitably programmed through central electronics module 802. Another example functionality of central electronics module 802 is to distribute incoming reference signal 404 from LO 312 to the multiple instances of electronic circuits 130. Reference signal 404 from LO 312 may be sent to mixer module 810 suitably through microcontroller 604 and DUT measurement module 806 in some embodiments.

In various embodiments, power module 804 may include suitable electrical circuits to enable power delivery to DUT 110 and other components in electronic circuits 130A. DUT measurement module 806 may include LPF 410 and ADC 414 as well as circuits to collect temperature sensor measurements from DUT 110. In some embodiments, other characteristics of DUT 110 may also be measured, such as voltage, current, etc.; electrical circuits to enable such measurements may also be provisioned in DUT measurement module 806 suitably. DUT communication module 808 may include various communication circuitry to communicate with DUT 110, for example, comprising instructions to turn on, turn off, etc. during testing. Mixer module 810 comprises mixer circuit 406 (including any buffer circuits) in various embodiments. In some embodiments, mixer module 810 may be located proximate to thermal chamber 102 and central electronics module 802 may be located distant from thermal chamber 102 with the remaining components of electronic circuits 130 in between on measurement board 104. Various other configurations may be used without departing from the scope of the embodiments.

Although the present disclosure has been described in detail with reference to particular arrangements and configurations, these example configurations and arrangements may be changed significantly without departing from the scope of the present disclosure. For example, although the present disclosure has been described with reference to particular types of components, system 100 may be implemented using other components that perform substantially the same functions in similar ways. Moreover, although system 100 has been illustrated with reference to particular elements and operations that facilitate various control system process, these elements, and operations may be replaced by any suitable architecture or process that achieves the intended functionality of system 100. Further, additional components such as resistors, capacitors, inductors, switches, diodes, thermocouples, oscillators, connectors, transistors, ICs, memory circuits, storage devices, etc. may be included in system 100 without departing from the scope of the embodiments. Some or all of the functionalities described herein may be consolidated into one or few components in some embodiments; in other embodiments, each functionality may be provisioned in a separate component without departing from the scope of the embodiments.

### Example Methods

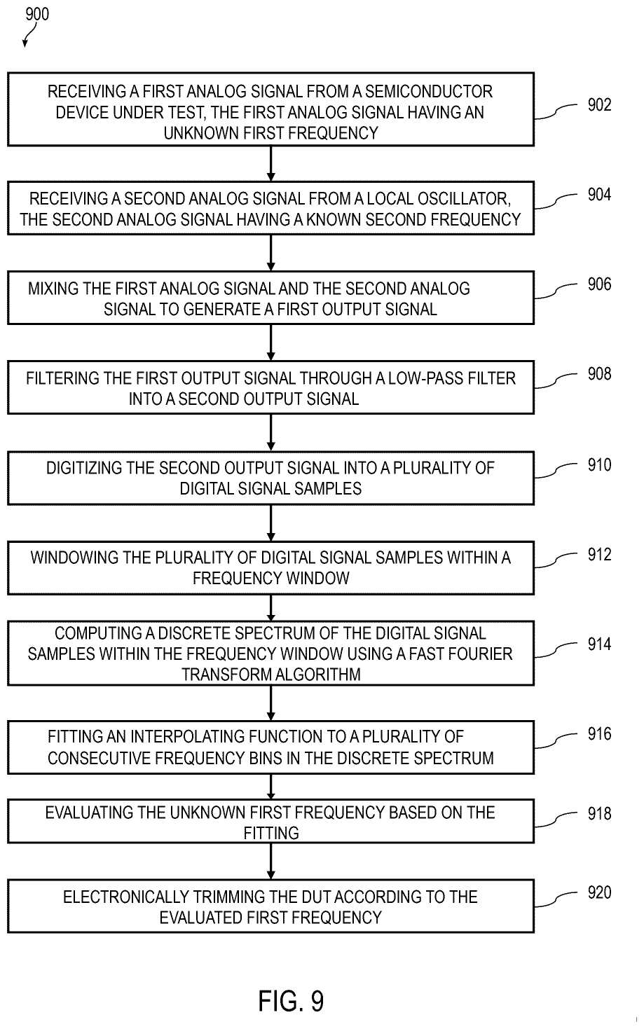

FIG. 9 is a simplified flow diagram of an example method 900 for massively parallel trimming of semiconductor devices according to some embodiments disclosed herein. At 902, mixer circuit 406 receives a first analog signal (e.g., measurement signal 402) from a semiconductor DUT 110, the first analog signal having an unknown first frequency. At 904, mixer circuit 406 receives a second analog signal (e.g., reference signal 404) from LO 312, the second analog signal having a known second frequency. At 906, mixer circuit 406 mixes the first analog signal with the second analog signal to generate a first output signal (e.g., output signal 408). At 908, LPF 410 filters the first output signal into a second output signal (e.g., filtered signal 412). At 910, ADC 414 digitizes the second output signal into a plurality of digital signal samples (e.g., digital signal 416). At 912, windowing module 418 applies a frequency window (e.g., Gaussian window) to the plurality of digital signal samples. At 914, FFT algorithm 424 computes discrete spectrum 426 of the plurality of digital signal samples within the frequency window. At 916, fitting algorithm 428 fits an interpolating function 430 to a plurality of consecutive frequency bins in discrete spectrum 426. At 918, fitting algorithm 428 may evaluate the unknown first frequency based on the fitting as result 432, which is the apex of interpolating function 430. At 920, DUT 110 may be electronically trimmed according to the evaluated first frequency.

In various embodiments, the operations described in FIG. 9 are performed automatically without human intervention. Although FIG. 9 illustrates various operations performed in a particular order, this is simply illustrative, and the operations discussed herein may be reordered and/or repeated as suitable. Further, additional operations which are not illustrated may also be performed without departing from the scope of the present disclosure. Also, various ones of the operations discussed herein with respect to FIG. 9 may be modified in accordance with the present disclosure to facilitate operations of system 100 as disclosed herein. Although various operations are illustrated in FIG. 9 once each, the operations may be repeated as often as desired.

It is important to note that the operations described with reference to the preceding figures illustrate only some of the possible scenarios that may be executed by, or within, system 100. Some of these operations may be deleted or removed where appropriate, or these steps may be modified or changed considerably without departing from the scope of the discussed concepts. In addition, the timing of these operations may be altered considerably and still achieve the results taught in this disclosure. The preceding operational flows have been offered for purposes of example and discussion.

### SELECT EXAMPLES

Example 1 provides a method, comprising: receiving a first analog signal from a semiconductor DUT, the first analog signal having an unknown first frequency; receiving a second analog signal from a local oscillator, the second analog signal having a known second frequency; mixing the first analog signal and the second analog signal to generate a first output signal; filtering the first output signal through a low-pass filter into a second output signal; digitizing the second output signal into a plurality of digital signal samples; windowing the plurality of digital signal samples within a frequency window; computing a discrete spectrum of the plurality of digital signal samples within the frequency window using an FFT algorithm; fitting an interpolating function to a plurality of consecutive frequency bins in the discrete spectrum; evaluating the unknown first frequency as an apex of the interpolating function; and electronically trimming the DUT according to the evaluated first frequency.

Example 2 provides the method of example 1, in which a Gaussian window is used for windowing the plurality of digital signal samples, and the interpolating function is a Gaussian function.

Example 3 provides the method of any one of examples 1-2, in which the unknown first frequency differs from the known second frequency by a differential in an order of parts per billion. Example 4 provides the method of any one of example 1-2, in which the unknown first

frequency differs from a target frequency by a differential in an order of less than parts per billion, and the known second frequency is a sum of the target frequency and a known offset frequency.

Example 5 provides the method of any one of examples 1-3, further comprising subjecting the DUT to a thermal range between a minimum temperature and a maximum temperature.

Example 6 provides the method of example 5, further comprising evaluating the unknown first frequency at different temperatures within the thermal range.

Example 7 provides an apparatus, comprising: a first printed circuit board having a first portion to be enclosed in a thermal chamber, and a second portion to be in ambient room temperature; a connector in the first portion to removably couple to a corresponding interface of a second printed circuit board having at least one DUT in the thermal chamber; and electronic circuits in the second portion to execute operations comprising: mixing a first analog signal from the DUT and a second analog signal from a local oscillator to generate a first output signal, the first analog signal having an unknown first frequency and the second analog signal having a known second frequency; filtering the first output signal through a low pass filter into a second output signal; digitizing the second output signal into a plurality of digital signal samples; windowing the plurality of digital signal samples within a frequency window; computing a discrete spectrum of the plurality of digital signal samples within the frequency window using a Fast Fourier Transform (FFT) algorithm; fitting an interpolating function to a plurality of consecutive frequency bins in the discrete spectrum; and evaluating the unknown first frequency as an apex of the interpolating function.

Example 8 provides the apparatus of example 7, in which the second printed circuit board has a plurality of DUTs, each DUT to generate a corresponding analog signal having an unknown frequency, the electronic circuits comprise a plurality of sets corresponding to the plurality of DUTs, each set comprises a different instance of a mixer circuit, a low pass filter circuit, and an analog-to-digital circuit, and a microcontroller circuit is common to the plurality of sets.

Example 9 provides the apparatus of any one of examples 7-8, in which the connector is a double-sided spring-loaded pogo pin interface.

Example 10 provides the apparatus of any one of examples 7-9, in which the connector is operable between a minimum temperature and a maximum temperature of the thermal chamber.

Example 11 provides the apparatus of any one of examples 7-10, in which the first printed circuit board includes conductive traces in an intermediate portion conductively coupling the connector in the first portion with the electronic components in the second portion.

Example 12 provides the apparatus of any one of examples 7-11, in which the electronic circuits comprise a mixer circuit; a low pass filter circuit; an analog-to-digital converter circuit; and a microcontroller circuit, the DUT and the local oscillator are conductively coupled to first inputs of the mixer circuit, a first output of the mixer circuit is conductively coupled to a second input of the low pass filter circuit, a second output of the low pass filter circuit is conductively coupled to a third input of the analog-to-digital converter circuit, and a third output of the analog-to-digital converter circuit is conductively coupled to a fourth input of the microcontroller circuit.

Example 13 provides the apparatus of example 12, in which the microcontroller circuit comprises: a window circuit to confine analysis within a frequency window, a Fast Fourier Transfer (FFT) algorithm circuit to perform an FFT analysis, and a fitting circuit to perform a best-fit analysis.

Example 14 provides the apparatus of any one of examples 7-13, in which the first printed circuit board comprises an intermediate portion between the first portion and the second portion, and the intermediate portion has no electronic components affixed thereto.

Example 15 provides a system, comprising: a thermal chamber; a first printed circuit board having a first portion inside the thermal chamber and a second portion outside the thermal chamber; a second printed circuit board removably coupled to the first portion of the first printed circuit board, the second printed circuit board being inside the thermal chamber, and having at least one DUT affixed thereto; and a local oscillator outside the thermal chamber conductively coupled to the second portion of the first printed circuit board, in which the second portion of the first printed circuit board includes electronic circuits to execute operations comprising: mixing a first analog signal from the DUT and a second analog signal from the local oscillator to generate a first output signal, the first analog signal having an unknown first frequency and the second analog signal having a known second frequency; filtering the first output signal through a low pass filter into a second output signal; digitizing the second output signal into a plurality of digital signal samples; windowing the plurality of digital signal samples within a frequency window; computing a discrete spectrum of the plurality of digital signal samples within the frequency window using an FFT algorithm; fitting an interpolating function to a plurality of consecutive frequency bins in the discrete spectrum; and evaluating the unknown first frequency as an apex of the interpolating function.

Example 16 provides the system of example 15, in which the thermal chamber has a thermally insulated slot on one side, and the first printed circuit board is positioned through the thermally insulated slot.

Example 17 provides the system of example 16, in which the first printed circuit board comprises an intermediate portion between the first portion and the second portion, the intermediate portion is in the thermally insulated slot, and the intermediate portion has no electronic components affixed thereto.

Example 18 provides the system of any one of examples 15-17, further comprising: a first plurality of the first printed circuit boards arranged in horizontal rows and vertical columns; and a second plurality of the second printed circuit boards arranged in vertical columns, in which one of the second printed circuit boards is removably coupled to multiple rows of the first printed circuit boards of a single vertical column.

Example 19 provides the system of example 18, in which the thermal chamber includes a plurality of thermally insulated slots, each slot corresponding to one of the first printed circuit boards.

Example 20 provides the system of any one of examples 18-19, in which the first plurality of first printed circuit boards is housed inside a lidded casing configured for air flow circulation.

The above description of illustrated implementations of the disclosure, including what is described in the abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

1. A method, comprising:
receiving a first analog signal from a semiconductor device under test (DUT), the first analog signal having an unknown first frequency;
receiving a second analog signal from a local oscillator, the second analog signal having a known second frequency;
mixing the first analog signal with the second analog signal to generate a first output signal;
filtering the first output signal through a low-pass filter into a second output signal;
digitizing the second output signal into a plurality of digital signal samples;
windowing the plurality of digital signal samples within a frequency window;
computing a discrete spectrum of the plurality of digital signal samples within the frequency window using a Fast Fourier Transform (FFT) algorithm;
fitting an interpolating function to a plurality of consecutive frequency bins in the discrete spectrum;
evaluating the unknown first frequency as an apex of the interpolating function; and
electronically trimming the DUT according to the evaluated first frequency.

2. The method of claim 1, wherein:
a Gaussian window is used for windowing the plurality of digital signal samples, and
the interpolating function is a Gaussian function.

3. The method of claim 1, wherein the unknown first frequency differs from the known second frequency by a differential in an order of less than parts per billion.

4. The method of claim 1, wherein:
the unknown first frequency differs from a target frequency by a differential in an order of less than parts per billion, and
the known second frequency is a sum of the target frequency and a known offset frequency.

5. The method of claim 1, further comprising subjecting the DUT to a thermal range between a minimum temperature and a maximum temperature.

6. The method of claim 5, further comprising evaluating the unknown first frequency at different temperatures within the thermal range.

7. An apparatus, comprising:
a first printed circuit board having a first portion to be enclosed in a thermal chamber, and a second portion to be in ambient room temperature;
a connector in the first portion to removably couple to a corresponding interface of a second printed circuit board having at least one device under test (DUT) in the thermal chamber; and
electronic circuits in the second portion to execute operations comprising:
mixing a first analog signal from the DUT and a second analog signal from a local oscillator to generate a first output signal, the first analog signal having an unknown first frequency and the second analog signal having a known second frequency;
filtering the first output signal through a low pass filter into a second output signal;
digitizing the second output signal into a plurality of digital signal samples;
windowing the plurality of digital signal samples within a frequency window;
computing a discrete spectrum of the plurality of digital signal samples within the frequency window using a Fast Fourier Transform (FFT) algorithm;
fitting an interpolating function to a plurality of consecutive frequency bins in the discrete spectrum; and
evaluating the unknown first frequency as an apex of the interpolating function.

8. The apparatus of claim 7, wherein:
the second printed circuit board has a plurality of DUTs, each DUT to generate a corresponding analog signal having an unknown frequency,
the electronic circuits comprise a plurality of sets corresponding to the plurality of DUTs,
each set comprises a different instance of a mixer circuit, a low pass filter circuit, and an analog-to-digital circuit, and
a microcontroller circuit is common to the plurality of sets.

9. The apparatus of claim 7, wherein the connector is a double-sided spring-loaded pogo pin interface.

10. The apparatus of claim 7, wherein the connector is operable between a minimum temperature and a maximum temperature of the thermal chamber.

11. The apparatus of claim 7, wherein the first printed circuit board includes conductive traces in an intermediate portion conductively coupling the connector in the first portion with the electronic circuits in the second portion.

12. The apparatus of claim 7, wherein:
the electronic circuits comprise a mixer circuit; a low pass filter circuit; an analog-to-digital converter circuit; and a microcontroller circuit,
the DUT and the local oscillator are conductively coupled to first inputs of the mixer circuit,
a first output of the mixer circuit is conductively coupled to a second input of the low pass filter circuit,
a second output of the low pass filter circuit is conductively coupled to a third input of the analog-to-digital converter circuit, and
a third output of the analog-to-digital converter circuit is conductively coupled to a fourth input of the microcontroller circuit.

13. The apparatus of claim 12, wherein the microcontroller circuit comprises: a window circuit to confine analysis within a frequency window, a Fast Fourier Transfer (FFT) algorithm circuit to perform an FFT analysis, and a fitting circuit to perform a best-fit analysis.

14. The apparatus of claim 7, wherein:
the first printed circuit board comprises an intermediate portion between the first portion and the second portion, and
the intermediate portion has no electronic components affixed thereto.

15. A system, comprising:
a thermal chamber;
a first printed circuit board having a first portion inside the thermal chamber and a second portion outside the thermal chamber;
a second printed circuit board removably coupled to the first portion of the first printed circuit board, the second printed circuit board being inside the thermal chamber, and having at least one device under test (DUT) affixed thereto; and
a local oscillator outside the thermal chamber conductively coupled to the second portion of the first printed circuit board, wherein:
the second portion of the first printed circuit board includes electronic circuits to execute operations comprising:
mixing a first analog signal from the DUT and a second analog signal from the local oscillator to generate a first output signal, the first analog signal having an unknown first frequency and the second analog signal having a known second frequency;
filtering the first output signal through a low pass filter into a second output signal;
digitizing the second output signal into a plurality of digital signal samples;
windowing the plurality of digital signal samples within a frequency window;
computing a discrete spectrum of the plurality of digital signal samples within the frequency window using a Fast Fourier Transform (FFT) algorithm;
fitting an interpolating function to a plurality of consecutive frequency bins in the discrete spectrum; and
evaluating the unknown first frequency as an apex of the interpolating function.

16. The system of claim 15, wherein:
the thermal chamber has a thermally insulated slot on one side, and
the first printed circuit board is positioned through the thermally insulated slot.

17. The system of claim 16, wherein:
the first printed circuit board comprises an intermediate portion between the first portion and the second portion,
the intermediate portion is in the thermally insulated slot, and
the intermediate portion has no electronic components affixed thereto.

18. The system of claim 15, further comprising:
a first plurality of the first printed circuit boards arranged in horizontal rows and vertical columns; and
a second plurality of the second printed circuit boards arranged in vertical columns, wherein one of the second printed circuit boards is removably coupled to multiple rows of the first printed circuit boards of a single vertical column.

19. The system of claim 18, wherein the thermal chamber includes a plurality of thermally insulated slots, each slot corresponding to one of the first printed circuit boards.

20. The system of claim 18, wherein the first plurality of first printed circuit boards is housed inside a lidded casing configured for air flow circulation.
